(19) United States
(12) Patent Application Publication
(10) Pub. No.: US 2004/0089421 A1
(43) Pub. Date: May 13, 2004

(54) Distributed control system for semiconductor manufacturing equipment

(76) Inventors: Srinivasan M. Komandur, San Jose, CA (US); Jalal Ashjaee, Cupertino, CA (US)

Correspondence Address: Daniel Hopen, NuTool, Inc., 1655 McCandless Drive, Milpitas, CA, 95035, US

(21) Appl. No.: 10/697,199

(22) Filed: Oct. 31, 2003

Related U.S. Application Data
(63) Continuation-in-part of application No. 10/199,924, filed on Jul. 19, 2002.
(60) Provisional application No. 60/357,148, filed on Feb. 15, 2002.

(51) Int. Cl. H01L 21/306

(52) U.S. Cl. 156/345.32; 156/345.24

(57) ABSTRACT

A semiconductor workpiece processing tool comprises a plurality of process modules for processing the workpiece, where a number of the process modules include a robot loading window. A control system is included for managing operation of the processing tool including a production route defining movement of the workpiece among a number of the process modules. The control system includes a user interface through which an operator can define the production route and recipes to be performed on the workpiece in each of the process modules, a system controller for controlling execution of the production route, a process module controller associated with each of the process modules for controlling the processing of the workpiece in the process module, and a network connecting the user interface, system controller and each process module controller. The control system is configured to select the next process module in the production route when a workpiece is substantially completed with an existing process in the production route.

### RELATED APPLICATIONS

This application is a continuation-in-part of Ser. No. 10/199,924 filed Jul. 19, 2002 (NT-257) claiming priority to Prov. No. 60/357,148, filed Feb. 15, 2002 (NT-228P), Ser. No. 10/264,726 filed Oct. 3, 2002 (NT-224), and Ser. No. 09/795,687 filed Feb. 27, 2001 (NT202) claiming priority to Prov. No. 60/259,676 filed Jan. 5, 2001 (NT-202P), all incorporated herein by reference.

### FIELD

The present invention relates to a distributed control system for semiconductor manufacturing equipment, and more particularly to a computer controlled apparatus and method for improving semiconductor processing.

### BACKGROUND

In the semiconductor industry, various processes can be used to deposit and etch materials on the workpieces, which may also be referred to as wafers. These processes are typically carried out by various machine tools, or may be carried out in the same tool using various chambers. Conventional processing chambers are designed in multiple processing stations or modules that are arranged in a cluster to form a cluster tool or system. Such cluster tools or systems are often used to process a multiple number of wafers at the same time. Generally, cluster tools are configured with multiple processing stations or modules and are designed for a specific operation. However in such conventional cluster tools, deposition and cleaning processing steps both typically require separate chambers. Consequently, a wafer is typically moved to another station or system in order to be processed and cleaned. Since the environment must be clean of contaminants, a robot is typically used to move the workpiece from one chamber to another inside the cluster tool.

A software control program is used to control the robot for moving the workpieces around in the tool (called a production route), and for loading recipes to each of the processing chambers. The software control program is typically loaded by an operator selecting from a number of available production routes and recipes through a user interface. The operator loads a particular process recipe that includes information such as the chambers that will be used to process the semiconductor wafer, the parameters for processing, and other information.

Maintenance and testing of the chambers is a major business issue since an improperly operating chamber may cause downtime, resulting in lost production revenues. Conventional machine tools require that the cluster tool be taken off-line for maintenance and testing. Consequently, a difficulty that arises in conventional equipment is that the individual chambers cannot necessarily be manually controlled while the equipment is in operation (i.e. the production route in running).

What is needed is a system that allows unused chambers to be manually controlled, tested and maintained while the equipment is in operation.

### SUMMARY

The present invention relates to a distributed control system for semiconductor manufacturing equipment, and more particularly to a computer controlled apparatus and method for improving semiconductor processing. The invention advantageously allows unused chambers to be manually controlled, tested and maintained while the equipment is in operation.

A semiconductor workpiece processing tool comprises a plurality of process modules for processing the workpiece, where a number of the process modules include a robot loading window. A control system is included for managing operation of the processing tool including a production route defining movement of the workpiece among a number of the process modules. The control system includes a user interface through which an operator can define the production route and recipes to be performed on the workpiece in each of the process modules, a system controller for controlling execution of the production route, a process module controller associated with each of the process modules for controlling the processing of the workpiece in the process module, and a network connecting the user interface, system controller and each process module controller. The control system is configured to select the next process module in the production route when a workpiece is substantially completed with an existing process in the production route.

In one aspect of the invention, the user interface is a graphical user interface. In another aspect of the invention, each process module controller is capable of retrieving the recipe over the network based on the recipe name. In yet another aspect of the invention, an off-line module may be configured to perform testing, maintenance or other operation while the production route is in operation.

Advantages of the invention include the ability to continue a production route while a process module is experiencing a fault condition, undergoing maintenance or testing, or other operation. As a result, the tool may continue in operation while selected process modules are tested, maintained or otherwise used to process workpieces. This feature of continued operation while certain process modules undergo maintenance and testing can result in significant productivity improvements since the production line does not need to stop when a process module is undergoing maintenance and testing.

### BRIEF DESCRIPTION OF THE DRAWINGS

The foregoing and other features, aspects, and advantages will become more apparent from the following detailed description when read in conjunction with the following drawings, wherein:

FIGS. 1A-B depict a cluster tool and control system according to an embodiment of the invention;

FIGS. 2A-C depict a user interface for the cluster tool according to an embodiment of the invention;

FIGS. 3A-C depict computer control elements of the control system according to an embodiment of the invention; and

FIGS. 4A-D are flow charts showing operation of the invention according to an embodiment of the invention.

### DETAILED DESCRIPTION

As will be described below, the present invention provides a distributed control system for semiconductor manufacturing equipment, and more particularly a computer controlled apparatus and method for improving semiconductor processing. Reference will now be made to the drawings wherein like numerals refer to like parts throughout.

A. Cluster Tool Modular Architecture

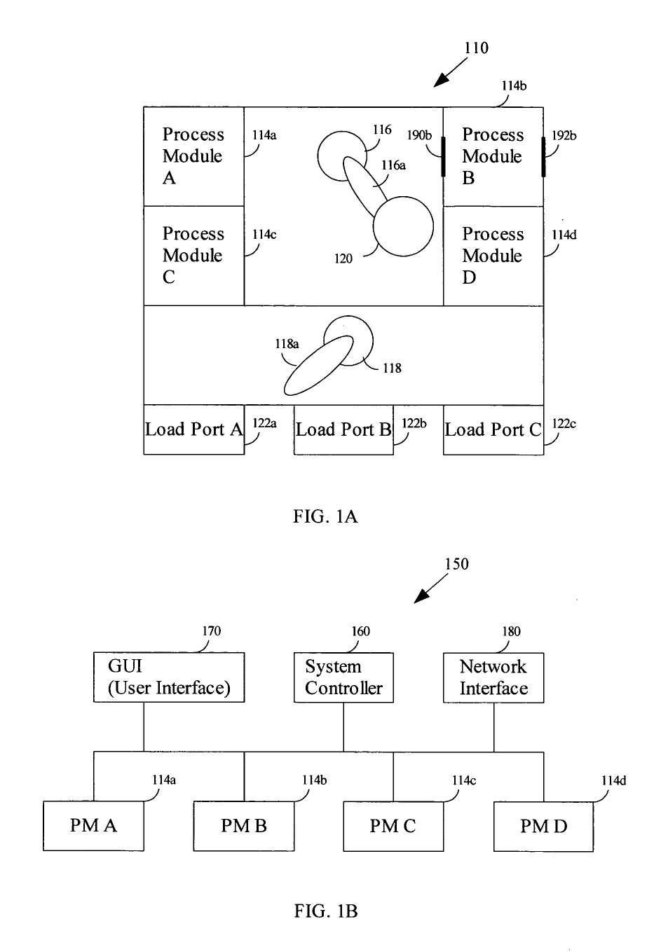

FIGS. 1A-B depict a cluster tool 110 and control system 150 according to an embodiment of the invention. The cluster tool 110 is a modular design that provides for a potential variety of process modules 114. The process modules may be of any type used in semiconductor processing, for example, chemical mechanical polishing (CMP), electro-chemical deposition (ECD), electro-chemical mechanical deposition (ECMD), electro-chemical mechanical polishing (ECMP), cleaning, annealing, etc. Robots 116 and 118 are provided inside the tool, which provides a mechanism for moving a workpiece 120 among the process modules. The workpiece is typically a silicon wafer that may have integrated circuits built therein. A detailed description of the tool is provided in Prov. No. 60/357,148, filed Feb. 15, 2002 and incorporated by reference herein.

The movement of the workpiece in the tool is called the production route, which is supervised by control system 150. The production route is important since it specifies the process modules that will be used during the processing. The production route may also include certain recipes that are performed in the various process modules. As shown, control system 150 includes a graphical user interface 170 (GUI) through which an operator can define the production route and recipes to be performed on the workpiece in each of the process modules. A system controller 160 is provided for controlling execution of the production route. Each of the process modules 114 includes a controller associated for controlling the processing of the workpiece in the process module. The control system components are coupled together as a local area network (LAN), which may have access through network interface 180 to a wide area network (WAN), or even a global network such as the Internet. This allows the tool to communicate with various other systems as described below.

The process modules 114 include a robot loading window and a manual loading window. For example, referring to FIG. 1A, process module B (114b) includes a robot window 190b and manual window 192b, and the other process modules 114a-114d have similar windows. However, the invention does not require that all the process modules have such windows because it may be desirable in some circumstances to have process modules that only have one or the other window. The robot loading window is inside the machine and accessible to the robot. The manually loading window is on the outside of the machine for operator access. One advantage to the manual access window is that an operator can perform maintenance and testing on the process chambers as needed. It is not necessary that all of the process modules have manual loading windows.

While four process modules 114a-114d are depicted, any number may be used in the invention. Likewise, while two robots 116 and 118, and three load ports 122a-122c are depicted, any number may be used in the invention.

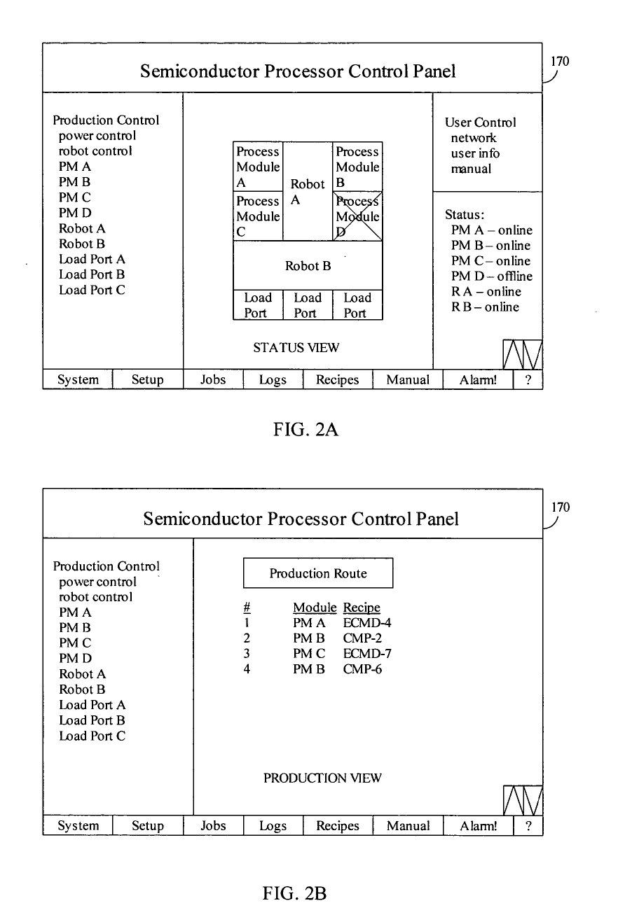

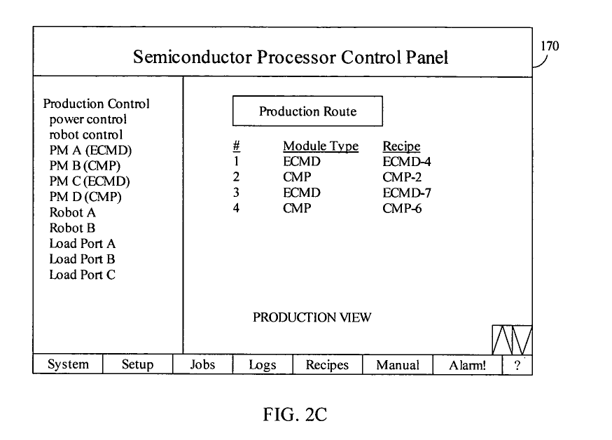

FIGS. 2A-C depict a user interface 170 for the cluster tool according to an embodiment of the invention. The user interface provides an operator with the ability to view the status of the tool and determine which process modules are on-line and off-line, as shown in FIG. 2A. It also allows the operator to set up the production route and select various recipes that will be used by the process modules on the workpiece, as shown in FIG. 2B. In one aspect of the invention shown in FIG. 2C, the type of process can be defined by the recipe rather than a specific module. Interface is a touch screen apparatus, but can also include other interface components such as a keyboard, pointing device, etc.

In one aspect of the invention, the production route includes a number of on-line process modules defined in the production route. In the exemplary aspect, at least one off-line process module is not included in the production route. Referring to FIG. 2A, process modules A, B and C are on-line and process module D is off-line. An off-line process module can accept a workpiece through the manual window and to perform a recipe thereon. This feature of continued operation while certain process modules undergo maintenance and testing can improve productivity since the production line does not need to stop when a process module is undergoing maintenance and testing.

For each wafer, the system controller is also loaded with the name of the process sequence, or recipe name that is needed for that wafer, with various portions of the process sequence performed by different processing stations. When sending a particular wafer to a particular process module, the recipe name is sent in a command by the system controller to a processing station module, and that process can then take place, which then also allows tracking of the wafers that are being routed.

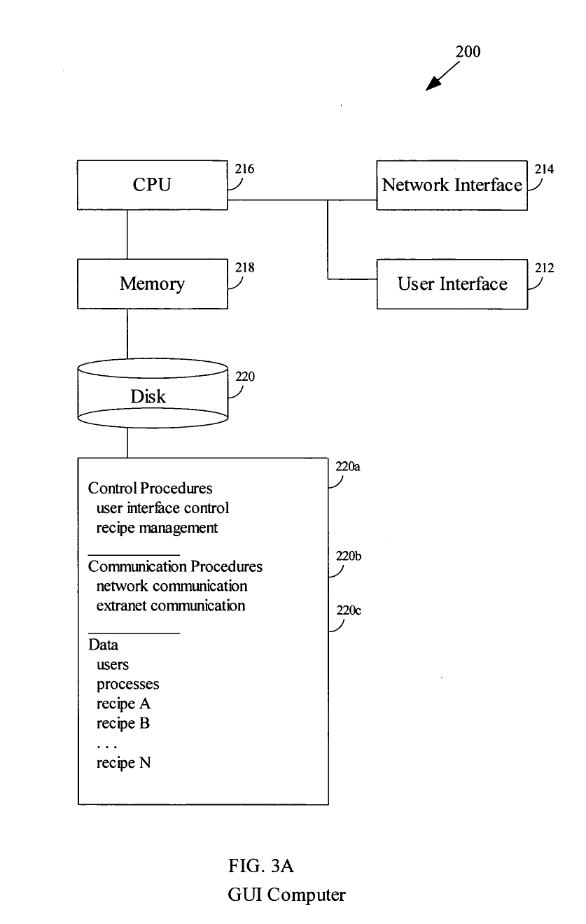

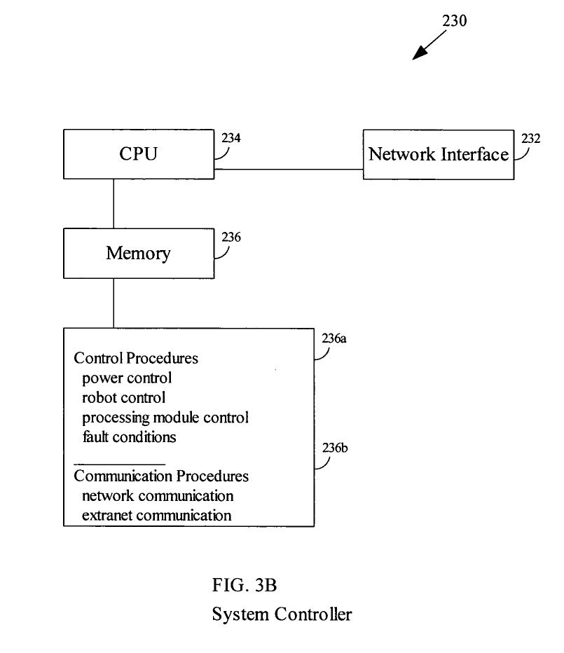

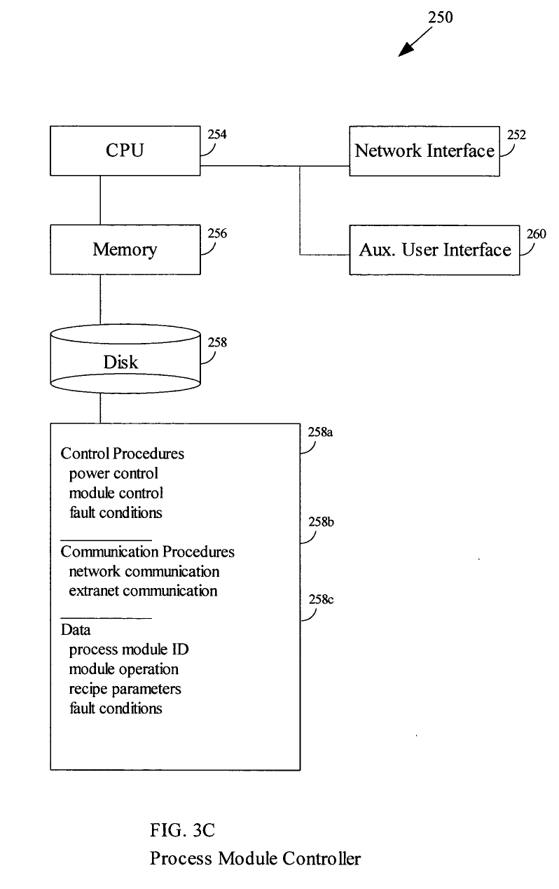

Each of the various subsystems that is referred to herein preferably contains a computer control that allows each of the various subsystems to operate in the integrated system and independently. During operation with the integrated system, the electronic control of each particular subsystem works with the system controller to ensure that operations with other subsystems and the wafer handling system are synchronized with the overall system operation. During operation of each subsystem independently, the electronic control of the particular subsystem is capable of controlling the operations performed by that particular subsystem. According to one aspect of the invention, an auxiliary user interface such as a computer terminal can be used when the subsystem is independently operated, which is described below with reference for FIG. 3C. Accordingly, since subsystems can be used together and independently, the same subsystems can be used in a greater variety of configurations, thus increasing their flexibility.

FIG. 2C shows that the production route can be identified by process type instead of strictly process module. In this example, PMA and PMC are ECMD modules while PM B and PM D are CMP modules. The route requires two ECMD steps that can be performed by PM A or PM C, and two CMP steps that can be performed by PM B or PM D. The route chosen by the system controller is the one that is most efficient to process the wafers and can be decided in real-time. For example, if a wafer has complete the first step, the system controller will poll PM B and PM D to determine which of these CMP modules is available and will route the wafer to the available module, if any. If one CMP module is busy or is experiencing a fault condition, then the wafer is routed to the other CMP module. Fault conditions can occur when a process module breaks or is due for maintenance. Maintenance on the process modules can include replacing materials, e.g. pads or chemicals, for the process. This flexibility in scheduling is performed in real-time when a wafer needs to be delivered to the next PM according to the production route. Alternatively, the production route can be determined in advance with alternate scheduling based on busy or fault conditions.

B. Control System

FIGS. 3A-C depict computer control elements of the control system according to an embodiment of the invention. FIG. 3A shows the graphical user interface (GUI) computer 200 that the operator interfaces with to program and monitor the tool. The GUI computer includes an interface 212 for the operator and a network interface 214 to communicate over the LAN with the other control system components. A central processing using 216 (CPU) controls the storage, communication and data processing, for example, production route selection and storage. A memory 218 and disk 220 store the routines necessary to operate the GUI and program, control and monitor the tool. The memory includes control procedures 220a that are used for the GUI control and recipe management, communication procedures 220b that are used for network communication, and data 220c that includes the users, processes (e.g. production routes), recipes, etc.

Referring to FIG. 3B, once the tool is commanded by the GUI to begin operation, a system controller 230 manages the production route. The control procedures 236a include power control, robot control, processing module control, and fault conditions. The system controller also includes standard communications procedures to communicate with the other network components over the LAN. In operation, the system controller manages the robot operation that delivers the workpieces to the process modules and retrieves the workpieces from the process modules. The system controller also informs the process modules of the particular recipe that they will perform.

Referring to FIG. 3C, the process module controller 250 has a substantially autonomous role in the system. The process module controller accepts the wafer from the robot under the control of the system controller and also receives the name of the recipe to be performed. The process module controller then seeks out the recipe, which may be stored within the tool at the GUI computer, outside the tool on another LAN and WAN, or elsewhere on an accessible network. The process module controller stores the recipe as data in its memory 258c. The control procedures 258a then execute the recipe and the communications procedures 258b inform the system controller when the process is complete.

In one aspect of the invention, as depicted in FIG. 3C, the process module controller can include an auxiliary user interface 260. This interface allows independent operator control over the process module, and supports the seamless operation of on-line and off-line process modules and the transition of the modules from on-line to off-line and vice-versa as required during operation, fault conditions, testing, maintenance and other routine operations.

While the modular cluster tool has been described with reference to possible configurations, an operational example will help to demonstrate additional features of the invention.

C. Operational Example

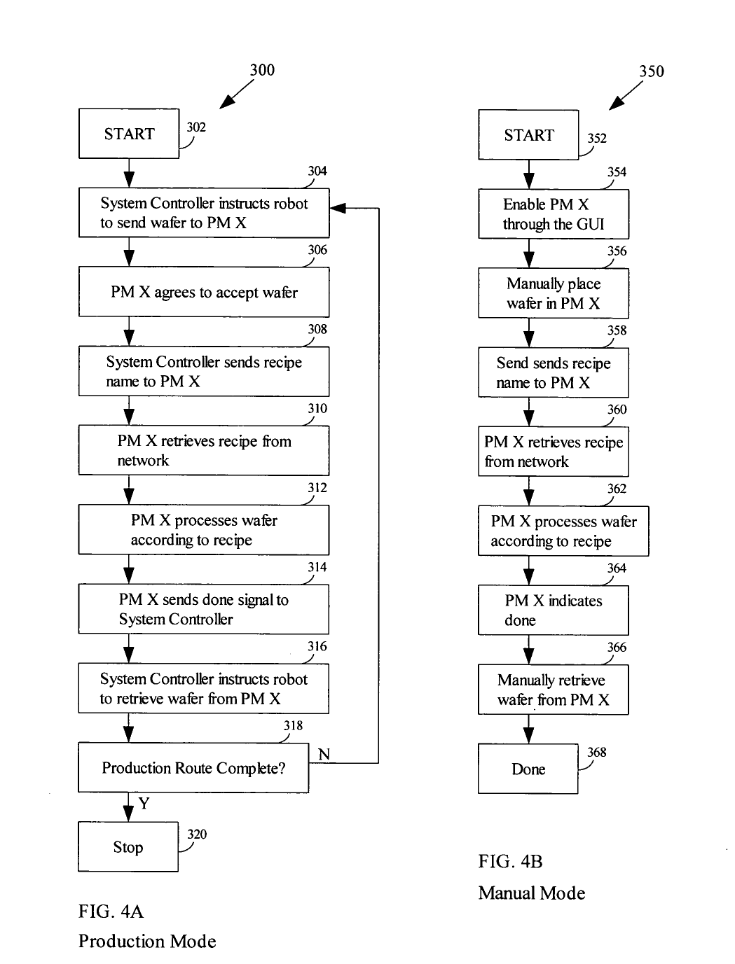

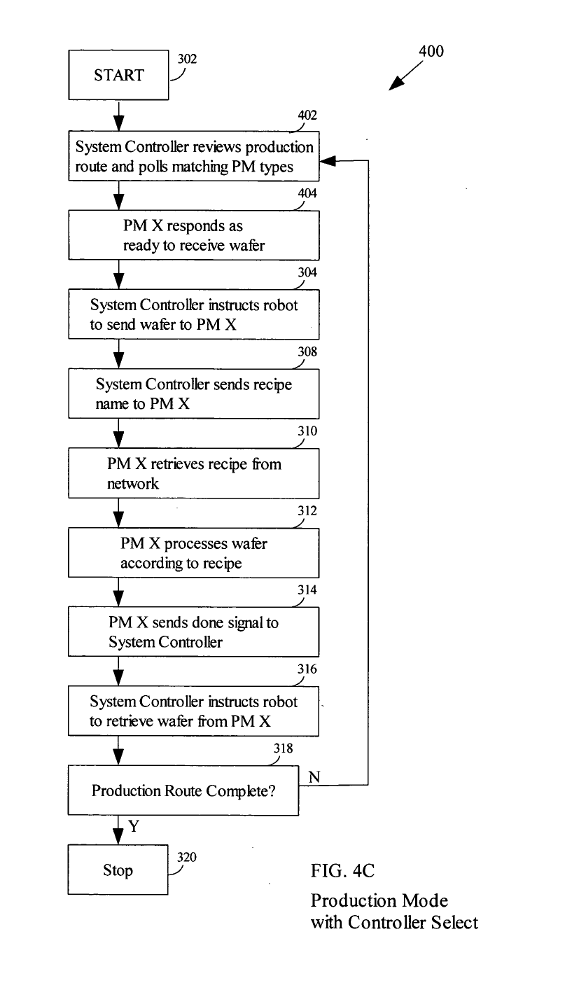

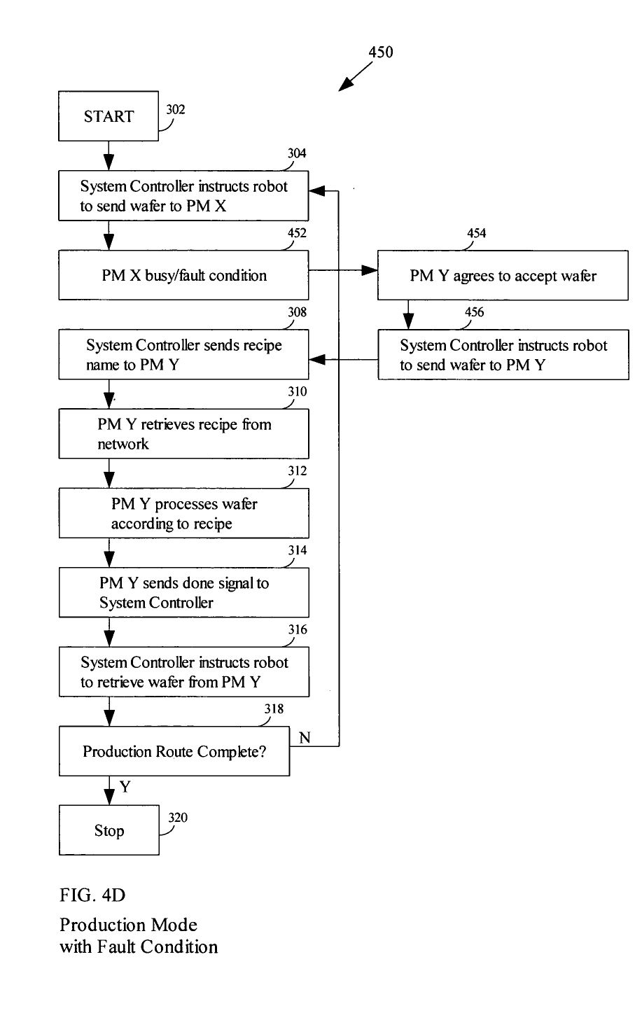

FIGS. 4A-B are flow charts showing operation of the invention according to an embodiment of the invention. These operational examples may be performed simultaneously if desired, but that is not required by the invention since there may be times when an operator may wish to manually operate several process modules without the tool performing a production route.

FIG. 4A shows a sample production route flowchart example 300 where at step 302 the workpiece is retrieved, for example, from a load port cassette and brought into the tool by the robot 118. In step 304, the system controller instructs the robot to send the wafer to process module X (PM X), where X is used as a reference to an arbitrary process module which would depend on the production route. In step 306, PM X agrees to accept the wafer, and in step 308, the system controller sends the recipe name to PM X. In step 310, PM X retrieves the recipe from the network, which could be the LAN, a WAN or other network. In step 312, PM X processes the wafer according to the recipe, and then in step 314, PM X sends a signal to the system controller indicating that the recipe is done. In step 316, the system controller instructs the robot to retrieve the wafer from PM X. If the production route is not complete, step 318 returns the production route processing to step 304 which continues the production route. If the production route is complete, step 320 ends the process and the robot returns the wafer to the load port cassette.

FIG. 4B is a flowchart 350 showing an exemplary manual operation where step 352 is the start of the flowchart. In step 354, process module X (PM X) is enabled through the GUI computer, where X is used as a reference to an arbitrary process module. In step 356, the wafer is manually inserted into PM X. In step 358, the operator sends the recipe to PM X using the GUI computer. In step 360, PM X retrieves the recipe from the network, which could be the LAN, a WAN or other network. In step 362, PM X processes the wafer according to the recipe, and then in step 364, PM X sends a signal to the GUI computer indicating that the recipe is done. In step 366, the wafer is manually retrieved from PM X by the operator, and then step 368 completes the operation. As stated above, these operational examples may be performed simultaneously if desired, but that is not required by the invention since there may be times when an operator may wish to manually operate several process modules without the tool performing an production route.

FIG. 4C is a flowchart 400 showing that the production route can be determined in real-time based on the next process module needed for the production route. The flowchart starts with step 401. Referring to step 402, the system controller reviews the production route and polls matching process module types. In step 404, the available process modules respond as ready to receive the wafer. In this example, in step 404, PM X responds as ready to receive the wafer. In step 304, the system controller instructs the robot to send the wafer to PM X. The process continues as described with reference to FIG. 4A modified as shown in FIG. 4C.

FIG. 4D is a flowchart 450 showing that the production route can be modified due to process module busy or fault conditions. Referring to step 452, the desired process module PM X has a busy or fault condition. The system controller reviews the production route and polls alternate matching process module types. In step 454, an alternate process module PM Y is available to accept the wafer. In step 456, the system controller instructs the robot to send the wafer to PM Y. The process continues as described with reference to FIG. 4A modified as shown in FIG. 4D.

D. Conclusion

Advantages of the invention include the ability to continue a production route while a process module is experiencing a fault condition, undergoing maintenance or testing, or other operation. As a result, the tool may continue in operation while selected process module are tested, maintained or otherwise used to process workpieces. This feature of continued operation while certain process modules undergo maintenance and testing can result in significant productivity improvements since the production line does not need to stop when a process module is undergoing maintenance and testing. Similarly, when a process module is ready to resume production, it will acknowledge module ready when polled and will be made part of the production route by the system controller. Accordingly, the present invention provides a robust cluster tool that seamlessly removes and incorporates process module in response to the readiness of the process module.

Having disclosed exemplary embodiments and the best mode, modifications and variations may be made to the disclosed embodiments while remaining within the subject and spirit of the invention as defined by the following claims

1. A semiconductor workpiece processing tool comprising:
a plurality of process modules for processing the workpiece, where a number of the process modules include a robot loading window;
a control system for managing operation of the processing tool including a production route defining movement of the workpiece among a number of the process modules, wherein the control system includes:
(a) a user interface through which an operator can define the production route and recipes to be performed on the workpiece in each of the process modules;
(b) a system controller for controlling execution of the production route;
(c) a process module controller associated with each of the process modules for controlling the processing of the workpiece in the process module; and
(d) a network connecting the user interface, system controller and each process module controller;
wherein the control system is configured to select the next process module in the production route when a workpiece is substantially completed with an existing process in the production route.

2. The processing tool of claim 1, wherein:
the production route includes a number of on-line process modules defined in the production route and at least one off-line process module not included in the production route.

3. The processing tool of claim 1, wherein:
the control system is configured to route the workpiece in the production route based at least in part on process module fault conditions.

4. The processing tool of claim 2, wherein:
the control system is configured to route the workpiece in the production route based at least in part on process module fault conditions.

5. The processing tool of claim 1, wherein:
each process module controller is capable of retrieving a recipe over the network based on a recipe identifier.

6. The processing tool of claim 3, wherein:
each process module controller is capable of retrieving a recipe over the network based on a recipe identifier.

7. The processing tool of claim 4, wherein:
each process module controller is capable of retrieving a recipe over the network based on a recipe identifier.

8. The processing tool of claim 5, wherein:
the system controller is configured to route the workpiece to an available process module based on the production route.

9. The processing tool of claim 6, wherein:
the system controller is configured to poll for an available process module based on the production route.

10. The processing tool of claim 5, wherein:
the system controller is configured to store process module status information and use the process module status information to determine the next process module in the production route.

11. The processing tool of claim 1, wherein:
a number of the process modules include a manual loading window; and
the production route includes a number of on-line process modules defined in the production route and at least one off-line process module not included in the production route that can be configured to perform testing, maintenance or other operation while the production route is in operation.

12. A method of processing a workpiece using a semiconductor workpiece processing tool including a plurality or process modules having a robot loading window and a control system including a user interface, system controller and process module controller associated with the process modules, comprising the steps of:
storing a production route defining movement of the workpiece among a number of the process modules;
storing a number of recipes for processing the workpiece, the recipes each having a unique name and a number of processing parameters associated therewith;
selecting the next process module in the production route when a workpiece is substantially completed with an existing process in the production route; and
moving the workpieces among the process modules in accordance with the selecting step.

13. The method of claim 12, wherein:
the production route includes a number of on-line process modules defined in the production route and at least one off-line process module not included in the production route.

14. The method of claim 12, wherein:
the selecting step routes the workpiece in the production route based at least in part on process module fault conditions.

15. The method of claim 13, wherein:
the selecting step routes the workpiece in the production route based at least in part on process module fault conditions.

16. The method of claim 12, further comprising the step of:
a selected process module retrieving a recipe over the network based on a recipe identifier.

17. The method of claim 14, further comprising the step of:
a selected process module retrieving a recipe over the network based on a recipe identifier.

18. The method of claim 15, further comprising the step of:
a selected process module retrieving a recipe over the network based on a recipe identifier.

19. The method of claim 16, wherein:
the selecting step routes the workpiece to an available process module based on the production route.

20. The method of claim 17, wherein:
the selecting step routes the workpiece to an available process module based on the production route.

21. The method of claim 16, further comprising the step of:
storing process module status information; and
wherein the selecting step includes the step of using the process module status information to determine the next process module in the production route.

22. The method of claim 12, wherein a number of the process modules include a manual loading window, and wherein:
the production route includes a number of on-line process modules defined in the production route and at least one off-line process module not included in the production route that can be configured to perform testing, maintenance or other operation while the production route is in operation.
